(19) United States
(12) Patent Application Publication
(10) Pub. No.: US 2016/0365445 A1
(43) Pub. Date: Dec. 15, 2016

(54) SEMICONDUCTOR DEVICE AND METHOD FOR MANUFACTURING THE SAME

(71) Applicant: Kabushiki Kaisha Toshiba, Minato-ku (JP)

(72) Inventors: Yasunori Oshima, Yokkaichi (JP); Toshihiko Iinuma, Yokkaichi (JP); Takayuki Ito, Yokkaichi (JP)

(73) Assignee: Kabushiki Kaisha Toshiba, Minato-ku (JP)

(21) Appl. No.: 14/835,909

(22) Filed: Aug. 26, 2015

Related U.S. Application Data
(60) Provisional application No. 62/174,732, filed on Jun. 12, 2015.

(51) Int. Cl. H01L 29/78; H01L 21/28; H01L 27/115

(52) U.S. Cl. CPC H01L 29/7843; H01L 27/11568; H01L 27/11582; H01L 21/28282

(57) ABSTRACT

According to one embodiment, a semiconductor device includes a semiconductor substrate, a first film, a conductive member and a second film. The first film is provided on the semiconductor substrate. The conductive member is provided in the first film, extends in a direction parallel to a main surface of the semiconductor substrate, and has a compressive stress. The second film is provided between the first film and the conductive member and has a tensile stress.

### CROSS-REFERENCE TO RELATED APPLICATIONS

This application is based upon and claims the benefit of priority from U.S Provisional Patent Application 62/174,732, filed on Jun. 6, 2015; the entire contents of which are incorporated herein by reference.

### FIELD

Embodiments described herein relate generally to a semiconductor device and a method for manufacturing the same.

### BACKGROUND

To highly integrate memory cells is effective for reducing a bit unit cost of a semiconductor device and increasing the capacity. In recent years, a semiconductor device is proposed in which memory cells are three-dimensionally stacked on a substrate in order to achieve high integration of the memory cells at low cost. In the three-dimensional stacked type semiconductor device as stated above, it is desired to suppress the occurrence of warp and deformation of the substrate at manufacturing stage

### BRIEF DESCRIPTION OF THE DRAWINGS

FIG. 1 is a sectional view illustrating a semiconductor device according to an embodiment;

FIG. 2 is an enlarged sectional view illustrating the inside of a slit of the semiconductor device according to the embodiment;

FIG. 3 is a schematic view for explaining a states of compressive stress and tensile stress in the semiconductor device according to the embodiment; and

FIG. 4 to FIG. 12 are process sectional views illustrating a method for manufacturing the semiconductor device according to the embodiment.

### DETAILED DESCRIPTION

In general, according to one embodiment, a semiconductor device includes a semiconductor substrate, a first film, a conductive member and a second film. The first film is provided on the semiconductor substrate. The conductive member is provided in the first film, extends in a direction parallel to a main surface of the semiconductor substrate, and has a compressive stress. The second film is provided between the first film and the conductive member and has a tensile stress.

An embodiment will be described hereinafter with reference to the accompanying drawings.

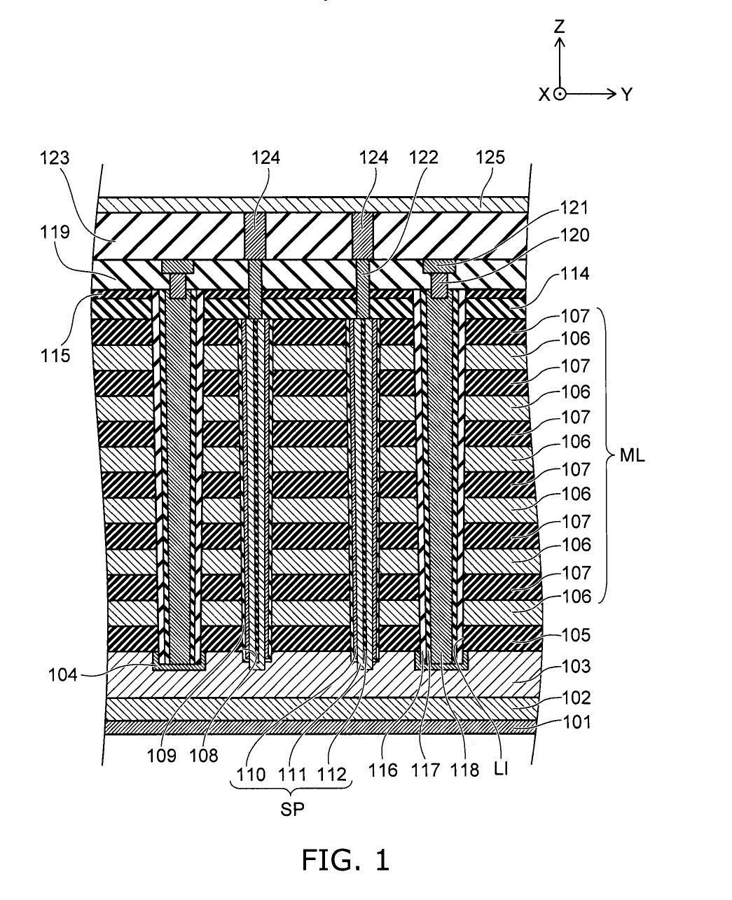

FIG. 1 is a sectional view illustrating a semiconductor device according to the embodiment.

As shown in FIG. 1, the semiconductor device 100 according to the embodiment includes a semiconductor substrate 101.

Hereinafter, for convenience of description, an XYZ orthogonal coordinate system is introduced.

In the coordinate system, two directions parallel to an upper surface of a semiconductor substrate 101 shown in FIG. 1 and orthogonal to each other are an X-direction and a Y-direction, and a direction orthogonal to both the X-direction and the Y-direction is a z-direction.

An n-type diffusion layer 102 is provided on the semiconductor substrate 101. A p-type diffusion layer 103 is provided on the n-type diffusion layer 102. An interlayer insulating film 105 is provided on the p-type diffusion layer 103. An n-type diffusion layer 104 is provided in a portion between the p-type diffusion layer 103 and the interlayer insulating film 105.

A stacked body ML including plural electrode films 106 and plural interelectrode insulating films 107 is provided on the interlayer insulating film 105. The stacked body ML is formed by alternately stacking the electrode films 106 and the interelectrode insulating films 107 in the Z-direction.

A memory hole 108 passing through the stacked body ML in the stacking direction, that is, in the Z-direction is formed in the stacked body ML. A memory film 109 is provided on an inside surface of the memory hole 108. The memory film 109 is a film capable of holding information. For example, the memory film 109 is a stacked film in which a block insulating layer, a charge storage layer and a tunnel insulating layer are stacked in sequence from the inner surface side of the memory hole 108.

The block insulating layer is a layer which prevents current from substantially flowing even if a voltage is applied within the driving voltage range of the semiconductor device 100, and contains, for example, a high dielectric constant material such as hafnium oxide. The charge storage layer is a layer capable of holding charge, and contains, for example, an insulating material such as silicon nitride. The tunnel insulating layer is a layer which usually has insulation properties, but flows tunnel current when a specified voltage in the driving voltage range of the semiconductor device 100 is applied, and contains, for example, an insulating material such as silicon oxide.

A semiconductor film 110 is provided on the memory film 109.

A semiconductor film 111 is provided on the semiconductor film 110 and a bottom of the memory hole 108. An insulating member 112 is embedded in the memory hole 108. The semiconductor films 110 and 111 and the insulating member 112 constitute a pillar SP. An insulating film 114 is provided on the stacked body ML. An insulating film 115 is provided on the insulating film 114.

A slit LI passing through the insulating films 115 and 114, the stacked body ML and the interlayer insulating film 105 is formed just above the n-type diffusion layer 104. The slit LI reaches the n-type diffusion layer 104. The shape of the slit LI is a groove shape extending in the X-direction. An insulating film 116 containing silicon oxide is provided on the inside surface of the slit LI. An insulating film 117 containing silicon nitride is provided on the insulating film 116. A conductive member 118 containing a conductive material such as tungsten (W) is provided in the slit LI. The conductive member 118 is embedded in the slit LI. A lower end of the conductive member 118 is connected to the n-type diffusion layer 104.

An insulating film 119 is provided on the insulating film 115. A plug 120 is provided just above the conductive member 118 and in a lower layer part of the insulating film 119. The plug 120 is connected to the conductive member 118. An interconnection 121 is provided just above the plug 120 and in an upper layer part of the insulating film 119. The interconnection 121 is connected to the conductive member 118 through the plug 120.

Besides, a plug 122 passing through the insulating films 119, 115 and 114 is provided just above the pillar SP. The plug 122 is connected to the pillar SP.

An insulating film 123 is provided on the insulating film 119. A plug 124 passing through the insulating film 123 is provided just above the plug 122. An interconnection 125 is provided on the insulating film 123.

The interconnection 125 is connected to the pillar SP through the plugs 124 and 122.

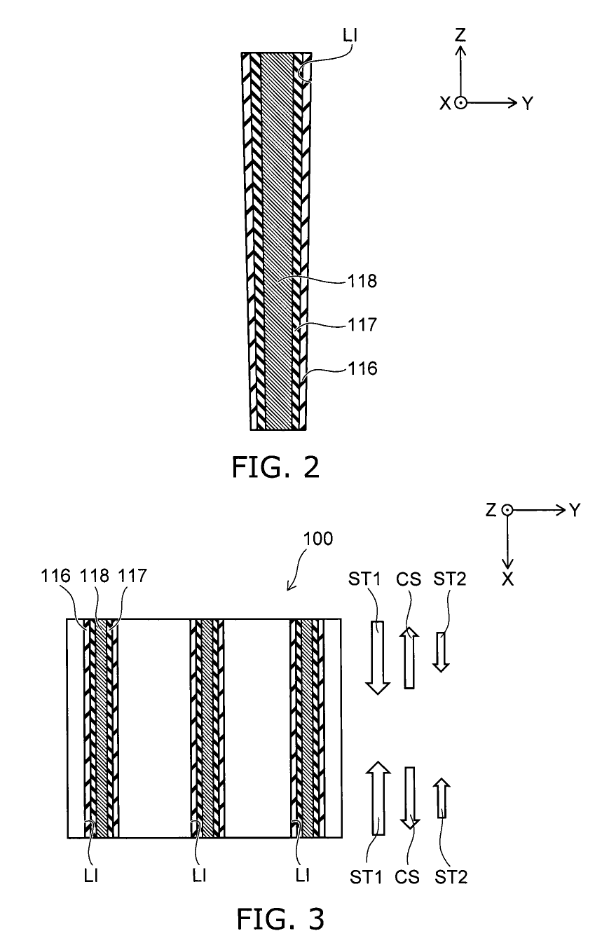

FIG. 2 is an enlarged sectional view illustrating the inside of the slit of the semiconductor device according to the embodiment.

FIG. 3 is a schematic view for explaining the states of compressive stress and tensile stress in the semiconductor device according to the embodiment.

Incidentally, for simplification of the illustration, members other than the insulating films 116 and 117 and the conductive member 118 are omitted in FIG. 3.

As shown in FIG. 2, the thickness of the insulating film 116 on the inside surface of the slit LI is thinner than the thickness of the conductive member 118 in the Y-direction. Besides, the thickness of the insulating film 117 is thinner than the thickness of the conductive member 118 in the Y-direction.

As shown in FIG. 3, in the semiconductor device 100 according to the embodiment, the plural slits LI extending in the X-direction are formed in the stacked body ML.

In the semiconductor device 100, a compressive stress ST1 in the X-direction is generated in the conductive member 118. Besides, a compressive stress ST2 in the X-direction is generated in the insulating film 116.

On the other hand, a tensile stress CS in the X-direction is generated in the insulating film 117 containing silicon nitride. That is, the stress in the opposite direction to the stress generated in the insulating film 116 and the conductive member 118 is generated in the insulating film 117. Thereby, the insulating film 117 relaxes the compressive stresses ST1 and ST2 of the insulating film 116 and the conductive member 118.

Next, a manufacturing method of the embodiment will be described.

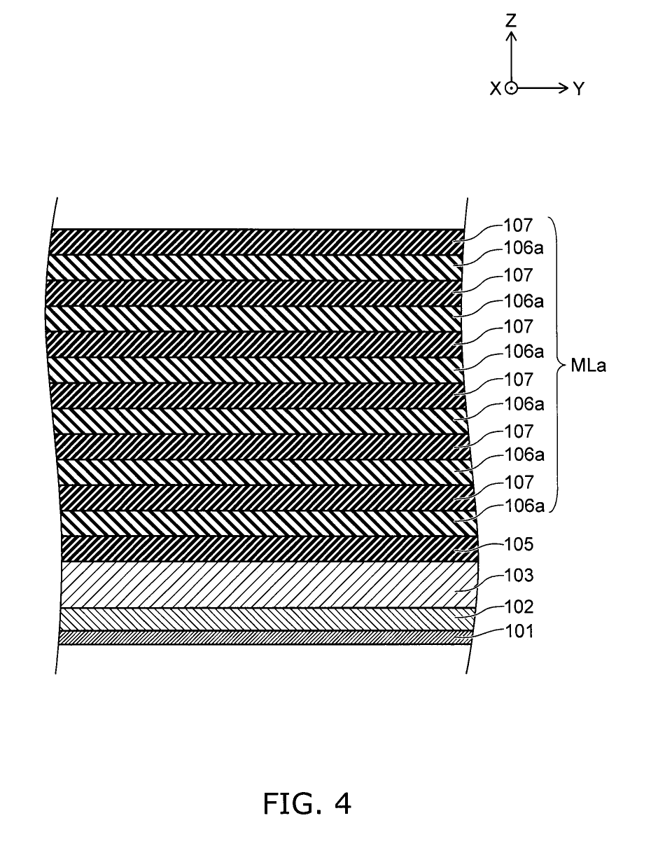

FIG. 4 to FIG. 12 are process sectional views illustrating a method for manufacturing the semiconductor device according to the embodiment.

First, as shown in FIG. 4, a semiconductor substrate 101 is prepared. The semiconductor substrate 101 is a part of a wafer. An impurity as a donor is ion-implanted into an upper layer part of the semiconductor substrate 101, so that an n-type diffusion layer 102 is formed. Next, an impurity as an acceptor is ion-implanted into an upper layer part of the n-type diffusion layer 102, so that a p-type diffusion layer 103 is formed.

Next, an interlayer insulating film 105 is formed on the p-type diffusion layer 103. Next, sacrifice films 106a and interelectrode insulating films 107 are alternately stacked on the interlayer insulating film 105, so that a stacked body MLa is formed.

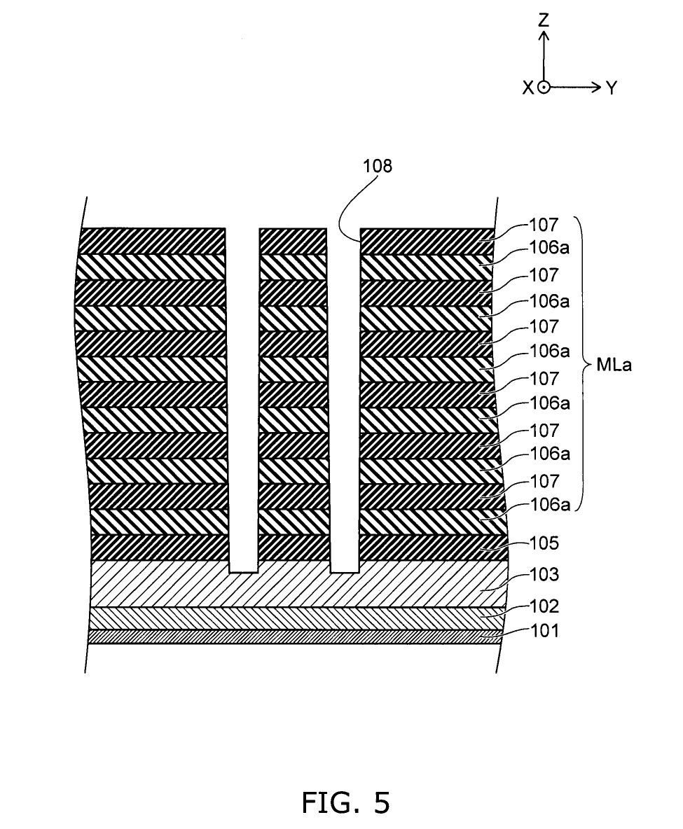

Next, as shown in FIG. 5, a cylindrical memory hole 108 extending in the Z-direction is formed in the stacked body MLa by anisotropic etching such as RIE (Reactive Ion Etching).

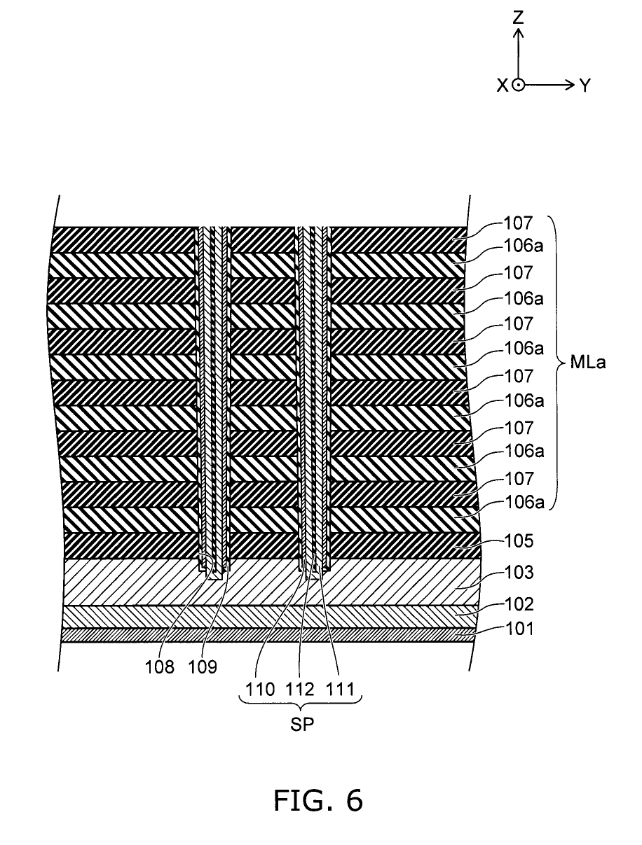

Next, as shown in FIG. 6, a memory film 109 is formed on an inner surface of the memory hole 108. For example, the memory film 109 is formed by stacking a block insulating layer, a charge storage layer and a tunnel insulating layer in sequence from the inner surface side of the memory hole 108. For example, the block insulating layer is formed by using a high dielectric constant material such as hafnium oxide. The charge storage layer is formed by using an insulating material containing silicon nitride. The tunnel insulating layer is formed by using an insulating material containing silicon oxide.

Thereafter, a semiconductor film 110 is formed on the memory film 109. Thereafter, the memory film 109 and the semiconductor film 110 covering the bottom of the memory hole 108 are selectively removed by anisotropic etching such as RIE. At this time, the memory film 109 and the semiconductor film 110 on the side surface of the memory hole 108 are made to remain. Thereby, the upper surface of the p-type diffusion layer 103 is exposed in the memory hole 108. Next, a semiconductor film 111 is formed in the memory hole 108. Thereby, the semiconductor film 111 is connected to the p-type diffusion layer 103. Next, an insulating member 112 is embedded in the memory hole 108. The semiconductor films 110 and 111 and the insulating member 112 constitute a pillar SP.

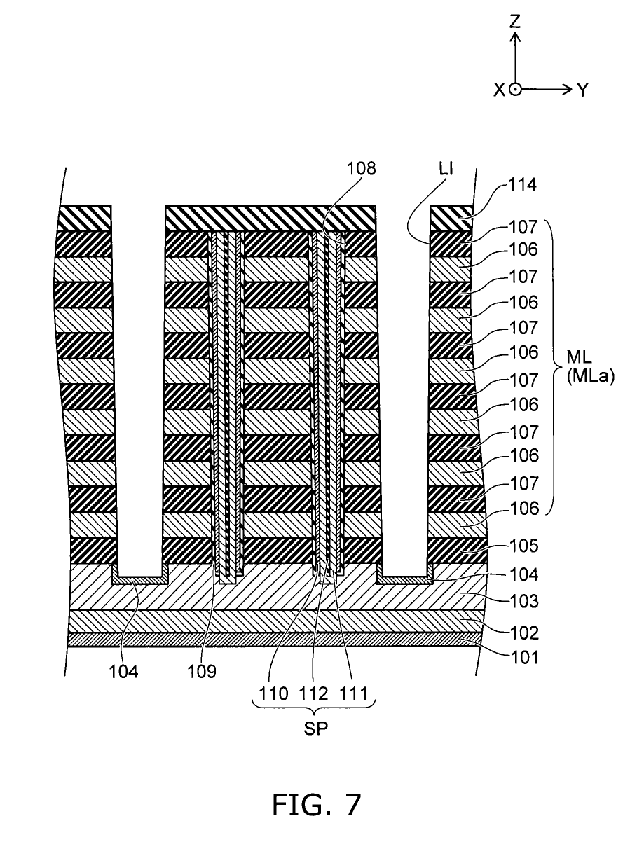

Next, as shown in FIG. 7, an insulating film 114 is formed on the stacked body MLa.

A slit LI passing through the insulating film 114, the stacked body MLa and the interlayer insulating film 105 is formed at a place different from the place where the pillar SP of the stacked body MLa is formed. The shape of the slit LI is a groove shape extending in the X-direction. The p-type diffusion layer 103 is exposed on the bottom of the slit LI. Next, the sacrifice film 106a is removed by etching such as wet etching through the slit LI. Thereby, a gap part 106 is formed between the interelectrode insulating films 107 adjacent to each other in the Z-direction. Thereafter, an electrode film 106 is formed in the gap part through the slit LI. Thereby, the stacked body MLa becomes the stacked body ML.

Next, an impurity as a donor is ion-implanted into a portion including the exposed surface of the p-type diffusion layer 103 at the bottom of the slit LI. Thereby, an n-type diffusion layer 104 is formed just below the slit LI and in an upper layer part of the p-type diffusion layer 103.

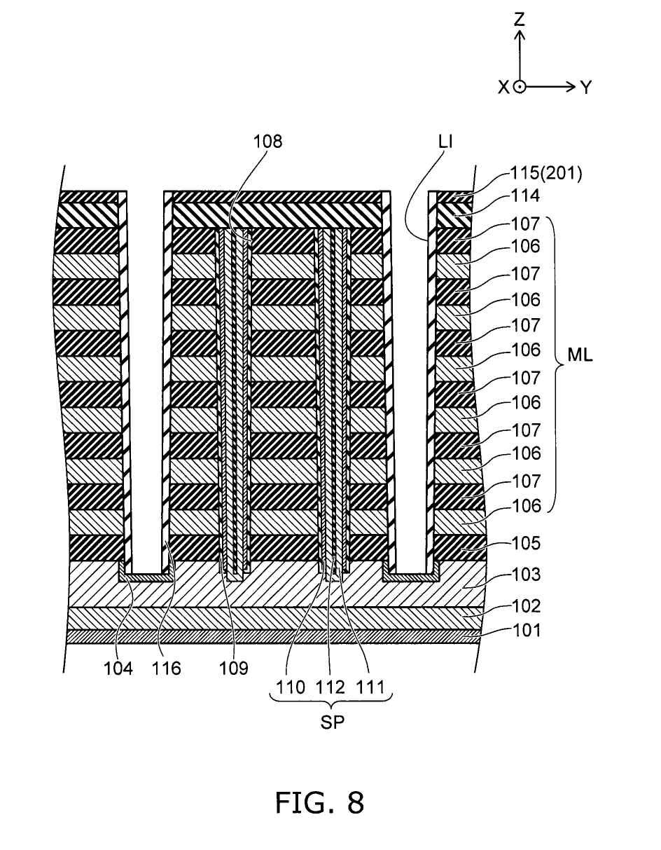

Next, as shown in FIG. 8, an insulating material such as silicon oxide is deposited on the whole surface, so that an insulating film 201 is formed.

Thereafter, the insulating film 201 formed on the bottom of the slit LI is selectively removed by anisotropic etching such as RIE. Thereby, the insulating film 201 remaining on the insulating film 114 becomes the insulating film 115, and the insulating film 201 remaining on the inside surface of the slit LI becomes the insulating film 116. The compressive stress in the X-direction is generated in the insulating film 116.

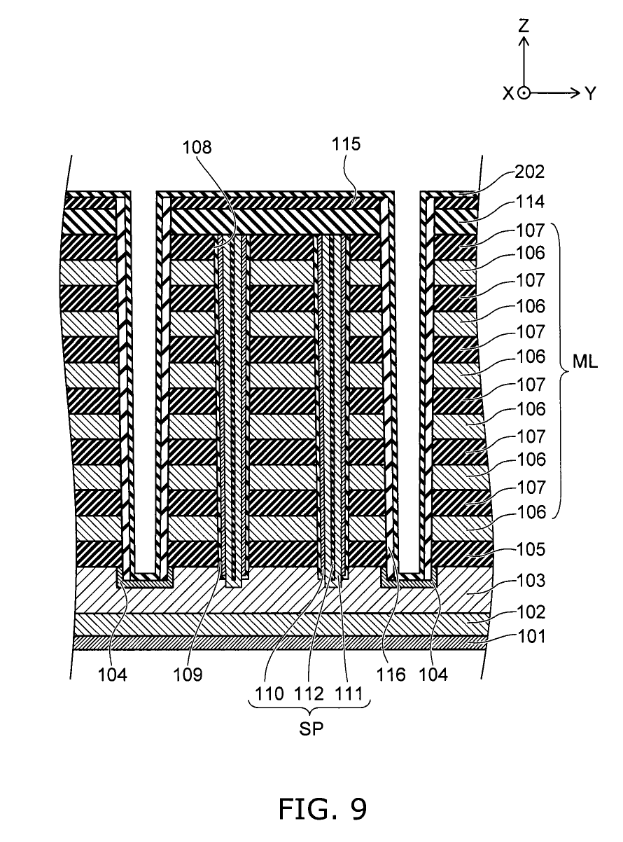

Next, as shown in FIG. 9, an insulating material containing silicon nitride is deposited on the whole surface, so that an insulating film 202 is formed. At this time, the insulating film 202 is formed by plasma ALD (Atomic Layer Deposition). An embedding property of the insulating film 202 in the slit LI can be adjusted by adjusting the condition of the plasma ALD. Besides, the stress of the insulating film 202 can be adjusted by adjusting a hydrogen plasma amount at the plasma ALD. For example, as the hydrogen plasma amount is decreased, the tensile stress of the insulating film 202 becomes high.

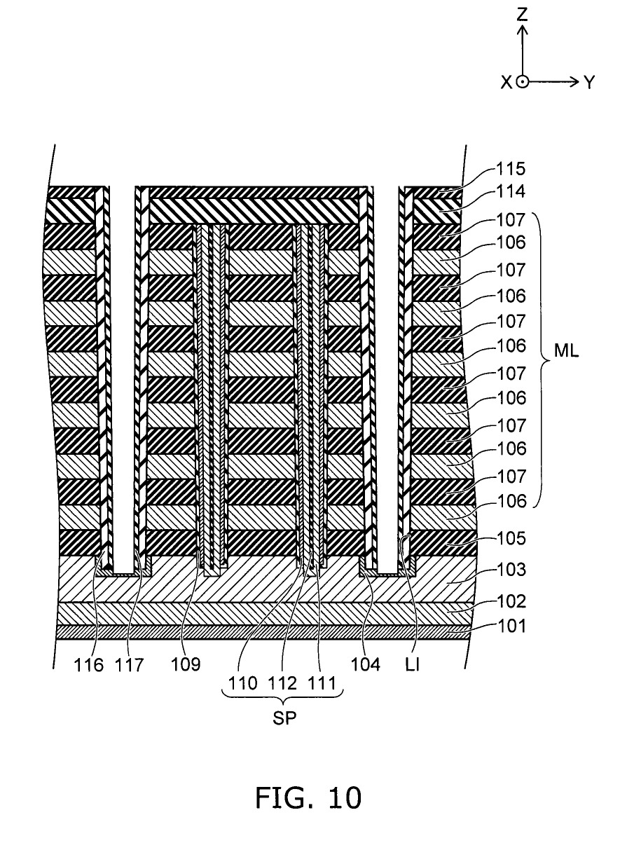

Next, as shown in FIG. 10, an etch-back process is performed, so that the insulating film 202 on the insulating film 115 and the bottom of the slit LI is selectively removed. At this time, the insulating film 202 remains on the inside surface of the slit LI. Besides, the upper surface of the n-type diffusion layer 104 is exposed on the bottom of the slit LI. Thereby, the insulating film 202 remaining on the inside surface of the slit LI becomes the insulating film 117. The tensile stress in the X-direction is generated in the insulating film 117.

Incidentally, the portions of the insulating films 201 and 202 formed on the bottom surface of the slit LI may be collectively removed by etching. That is, after the insulating film 201 is formed, the insulating film 202 is formed thereon. Then, the insulating film 202 on the insulating film 201 is selectively removed by an etch-back process. Then, the portion of the insulating film 201 formed on the bottom surface of the slit LI is removed by anisotropic etching such as RIE, so that the insulating films 116, 115 and 117 are formed in the slit LI.

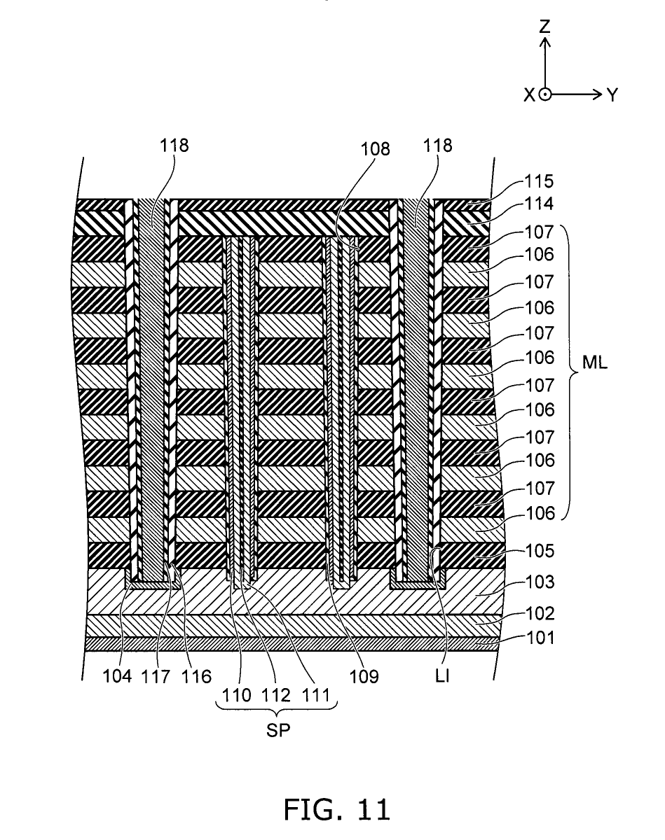

Next, as shown in FIG. 11, a conductive material such as tungsten is embedded in the slit LI. Thereby, a conductive member 118 is formed in the slit LI. The conductive member 118 is formed by, for example, a film growth method such as a CVD (Chemical Vapor Deposition) method.

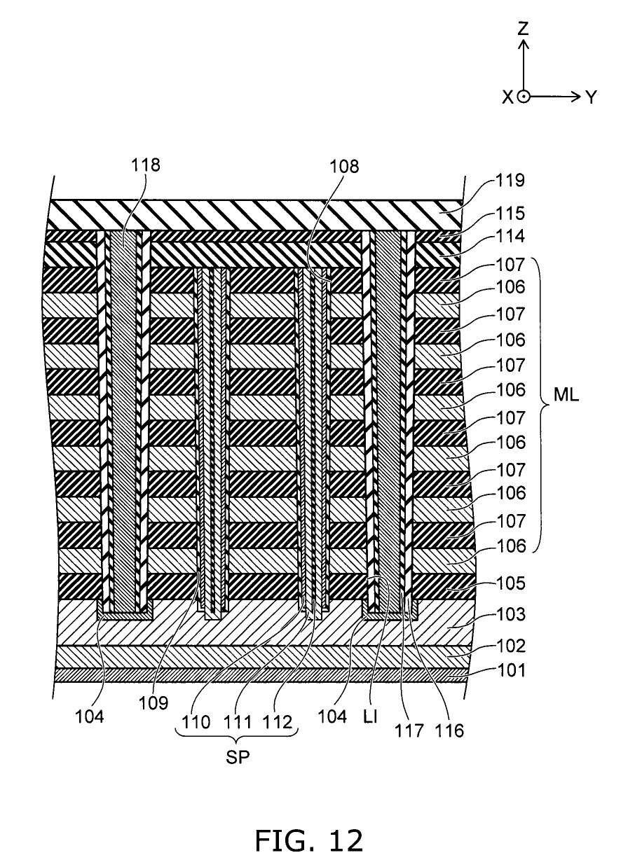

Next, as shown in FIG. 12, an insulating film 119 is formed on the insulating film 115.

Next, as shown in FIG. 1, an upper layer interconnection and a plug are formed by a well-known method. That is, the plug 120 and the interconnection 121 are formed in the insulating film 119 and just above the conductive member 118. Besides, the plug 122 passing through the insulating films 119, 115 and 114 is formed on the pillar SP. Further, the insulating film 123 is formed on the insulating film 119. Further, the plug 124 passing through the insulating film 123 is formed. Further, the interconnection 125 is formed on the plug 124.

Next, plural semiconductor devices 100 formed on the wafer are individualized by a dicing process.

The semiconductor device 100 is manufactured by the above processes.

Next, effects of the embodiment will be described.

In the embodiment, in the slit LI of the semiconductor device 100, the insulating film 117 containing silicon nitride is provided between the insulating film 116 containing silicon oxide and the conductive member 118 containing tungsten. The compressive stress in the X-direction is generated in the insulating film 116 and the conductive member 118.

If the insulating film 117 is not provided between the insulating film 116 and the conductive member 118, there is a possibility that the semiconductor device is warped and deformed by the compressive stress of the insulating film 116 and the conductive member 118. In this case, the characteristics are degraded due to the deformation of the semiconductor device.

On the other hand, in the embodiment, the tensile stress in the X-direction is generated in the insulating film 117. In this case, the compressive stress of the insulating film 116 and the conductive member 118 is relaxed by the tensile stress of the insulating film 117. Accordingly, the deformation of the semiconductor device 100 is suppressed, and the characteristics are stabilized. Besides, even if the number of stacked layers of the stacked body ML of the semiconductor device 100 is increased, the effect of suppressing the deformation can always be obtained.

Besides, in the manufacturing process, if the insulating film 117 is not formed, when the conductive member 118 is formed by the CVD method, the warp of the wafer as the semiconductor substrate 101 increases by the compressive stress of the conductive member 118. Thereby, the possibility that a process error at the time of transfer of the wafer and a decrease in yield are caused becomes high.

On the other hand, in the embodiment, since the tensile stress of the insulating film 117 relaxes the compressive stress of the conductive member 118, the warp of the wafer is suppressed, and the process error at the time of transfer of the wafer and the decrease in yield can be suppressed.

According to the embodiment described above, the semiconductor device having stable characteristics and the method for manufacturing the same can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor substrate;
a first film provided on the semiconductor substrate;
a conductive member provided in the first film, extending in a direction parallel to a main surface of the semiconductor substrate, and having a compressive stress; and
a second film provided between the first film and the conductive member and having a tensile stress.

2. The device according to claim 1, wherein
the first film includes a stacked body, and
the stacked body includes a plurality of conductive films and interelectrode insulating films alternately arranged with the plurality of conductive films in a stacked direction.

3. The device according to claim 2, further comprising:
a semiconductor pillar provided in the stacked body to be apart from the conductive member and extending in the stacking direction;
a charge storage film provided between the semiconductor pillar and the stacked body;
a tunnel insulating film provided between the semiconductor pillar and the charge storage film; and
a block insulating film provided between the stacked body and the charge storage film.

4. The device according to claim 3, wherein
the semiconductor pillar is substantially cylindrical, and
the charge storage film, the tunnel film and the block insulating film are cylindrically arranged on a side surface of the semiconductor pillar.

5. The device according to claim 1, wherein the second film contains silicon nitride.

6. The device according to claim 1, wherein the conductive member contains tungsten.

7. The device according to claim 1, further comprising an insulating film provided between the first film and the second film, wherein
the insulating film contains silicon oxide.

8. A method for manufacturing a semiconductor device; comprising:
forming a first film on a semiconductor substrate;
forming a slit in the first film;
forming a second film on an inside surface of the slit, the second film having a tensile; and
forming a conductive member having a compressive stress in the slit.

9. The method according to claim 8, wherein the forming the first film includes forming a stacked body as the first film by alternately stacking a third film and an interelectrode insulating film.

10. The method according to claim 9, further comprising:
removing the third film through the slit after the forming the slit and before the forming the second film; and
forming an electrode film through the slit in a space after the removing the third film and before the forming the second film.

11. The method according to claim 10, further comprising:
forming a memory hole extending in a stacking direction of the stacked body in the stacked body after the forming the first film and before the forming the slit;
forming a block insulating film in the memory hole and on a side surface of the third film after the forming the memory hole and before the forming the slit;
forming a charge storage member on the block insulating film after the forming the block insulating film and before the forming the slit;
forming a tunnel insulating film on an inside surface of the memory hole after the forming the charge storage member and before the forming the slit; and
forming a semiconductor pillar in the memory hole after the forming the tunnel insulating film and before the forming the slit.

12. The method according to claim 10, further comprising:
forming a cylindrical memory hole extending in a stacking direction of the stacked body in the stacked body after the forming the first film and before the forming the slit;
forming a cylindrical block insulating film on an inside surface of the memory hole after the forming the cylindrical memory hole and before the forming the slit;
forming a cylindrical charge storage film on a side surface of the block insulating film after the forming the cylindrical block insulating film and before the forming the slit;
forming a cylindrical tunnel insulating film on a side surface of the charge storage film after the forming the cylindrical charge storage film and before the forming the slit; and
forming a cylindrical semiconductor pillar in the memory hole after the forming the cylindrical tunnel insulating film and before the forming the slit.

13. The method according to claim 8, wherein the second film contains silicon nitride.

14. The method according to claim 8, further comprising:
forming an insulating film containing silicon oxide on an inside surface of the slit after the forming the slit in the first film and before the forming the second film.

15. The method according to claim 8, wherein the conductive member contains tungsten.

16. The method according to claim 13, wherein the second film containing the silicon nitride is formed by plasma atomic layer deposition.
